(19) United States
(12) Patent Application Publication
(10) Pub. No.: US 2013/0160841 A1
(43) Pub. Date: Jun. 27, 2013

(54) ADHESIVE COMPOSITION, FILM-LIKE ADHESIVE AND CIRCUIT CONNECTING MATERIAL USING THE SAME, CONNECTING STRUCTURE OF CIRCUIT MEMBER AND MANUFACTURING METHOD THEREOF

(71) Applicant: Susumu Kawakami, Tsukuba-shi (JP)

(72) Inventor: Susumu Kawakami, Tsukuba-shi (JP)

(73) Assignee: HITACHI CHEMICAL COMPANY, LTD., Tokyo (JP)

(21) Appl. No.: 13/561,477

(22) Filed: Jul. 30, 2012

Related U.S. Application Data
(60) Provisional application No. 61/513,325, filed on Jul. 29, 2011.

(51) Int. Cl. C09J 139/04; H01L 31/02; H05K 1/14

(52) U.S. Cl. CPC C09J 139/04; H05K 1/14; H01L 31/02008
USPC 136/256; 524/357; 252/519.21; 361/803; 228/175

(57) ABSTRACT

Provided is an adhesive composition containing an organoaluminum complex (A), a silane coupling agent (B), and a curable component (C).

### CROSS-REFERENCE TO RELATED APPLICATION

This application claims priority from U.S. Provisional Patent Application No. 61/513,325 filed Jul. 29, 2011, the entire disclosure of which is incorporated herein by reference.

### TECHNICAL FIELD

The present invention relates to an adhesive composition, a film-like adhesive and a circuit connecting material using the same, a circuit member connecting structure and a manufacturing method thereof.

### BACKGROUND ART

Various types of adhesive materials are used for fixing electronic parts or for connecting circuits in the field of semiconductors, liquid crystal displays, or the like.

Moreover, for connection between a liquid crystal display and a Tape Carrier Package (TCP), connection between a Flexible Printed Circuit (FPC) and a TCP, and connection between a FPC and a printed circuit board, an anisotropic conductive adhesive comprising conductive particles dispersed therein is used for the purpose of achieving circuit connection more reliably (for example, see Patent Literatures 1 to 4). Furthermore, recently, even when a semiconductor silicon chip is mounted on a board, so-called Chip-on-glass (COG) has been conducted, in which the semiconductor silicon chip is directly mounted on the board, instead of the conventional wire bonding, and the anisotropic conductive adhesive has been also applied here.
[Patent Literature 1] Japanese Patent Application Laid-Open No. 59-120436
[Patent Literature 2] Japanese Patent Application Laid-Open No. 60-191228
[Patent Literature 3] Japanese Patent Application Laid-Open No. 1-251787
[Patent Literature 4] Japanese Patent Application Laid-Open No. 7-90237

### SUMMARY OF THE INVENTION

### Problems to be Solved by the Invention

In recent years, in the field of precision electronic devices, circuits have been packed with a higher density, and then, width of electrodes and spacing between electrodes have become extremely small. Therefore, under the connection conditions of conventional circuit connecting adhesives using an epoxy resin, there are problems of falling off, peeling off, and positional displacement of wirings, and in the case of COG, there is a problem that warpage resulting from a difference in thermal expansion between a chip and a board occurs. Moreover, for the purpose of achieving lower cost, there is a need to improve a throughput, and an adhesive which can be cured at a low temperature (100 to 170° C.) for a short time (10 seconds or less), that is, a low-temperature rapid curable adhesive is demanded. Furthermore, in the case of the conventional circuit connecting adhesives using an epoxy resin, there is a problem that electric corrosion is liable to occur because a polymerization initiator used is an ionic compound and an epoxy polymer is a highly hydrophilic polyether. If radical polymerization of an unsaturated compound is applied to an adhesive material for COG, low-temperature rapid curing can be achieved; however, by the radical curing reaction in which a reaction point is neutral, it is difficult to form a bond based on radical reaction to an adherend composed of an inorganic material, and then, it is difficult to provide sufficient adhesion strength, and a problem is that the adhesion strength decreases especially under a high temperature and high humidity environment.

The present invention was made in view of the aforementioned problems of the conventional techniques, and an object of the present invention is to provide an adhesive composition which can provide sufficient adhesion strength even for an adherend composed of an inorganic material and provide stable adhesion strength even under a high temperature and high humidity environment, a film-like adhesive and a circuit connecting material using the same, and a circuit member connecting structure and a manufacturing method thereof.

### Means for Solving the Problems

Aiming at achieving the above object, the present inventors perfected the present invention upon discovering the fact that specifically higher adhesion strength can be achieved for an adherend composed of an inorganic material by using an organoaluminum complex and a silane coupling agent in combination in comparison with the case where the organoaluminum complex or the silane coupling agent is used alone.

That is, the adhesive composition of the present invention contains an organoaluminum complex (A), a silane coupling agent (B), and a curable component (C). By having such a composition, the adhesive composition of the present invention can provide sufficient adhesion strength even for an adherend composed of an inorganic material and provide stable adhesion strength even under a high temperature and high humidity environment for long period of time. Since the adhesive composition of the present invention has high adhesion strength for an adherend in which at least a surface is composed of an inorganic material, the adhesive composition of the present invention can be preferably used as a circuit connecting material.

The organoaluminum complex (A) may be one represented by formula (1). That is, the organoaluminum complex (A) may be one having a structure in which an alkoxy anion, a conjugated anion of β-diketone, or a conjugated anion of β-ketoester binds to a trivalent aluminum cation as a ligand.

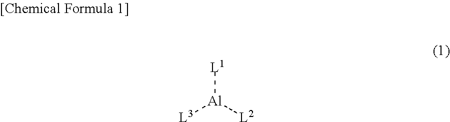

wherein, L¹, L², and L³ each independently represent an alkoxy anion, a conjugated anion of β-diketone, or a conjugated anion of β-ketoester; and L¹, L², and L³ may be the same or different from each other.

By employing the compound represented by formula (1) as the organoaluminum complex (A), it is possible to obtain more sufficient adhesion strength, and obtain more stable adhesion strength even under a higher temperature and higher humidity environment for long period of time.

The silane coupling agent (B) may be a methacryl group-containing silane coupling agent or an acryl group-containing silane coupling agent. By this, adhesive force is further improved.

The curable component (C) may be one comprising a radical polymerizable compound and a radical polymerization initiator. By this, in addition to the aforementioned effect, it is possible to lower adhesion temperature and shorten adhesion time (these are referred to as “low-temperature rapid curing” in combination) because radical polymerization of a radical polymerizable compound (for example, (meth)acrylate) can be applied at the time of curing. Furthermore, in the case of using this adhesive composition as a circuit connecting material, it is possible to reduce damage to a board and positional displacement when a circuit member is connected, and at the same time, improve production efficiency, because the low-temperature rapid curing can be achieved.

Moreover, the adhesive composition of the present invention may further contain a film forming material. It is possible to easily form the adhesive composition into a film shape because the adhesive composition contains the film forming material.

A film-like adhesive of the present invention is prepared by forming the aforementioned adhesive composition of the present invention into a film shape. This film-like adhesive is easy to handle, can be placed on the adherend such as a board easily, and connecting operations can be conducted easily.

A circuit connecting material of the present invention contains the aforementioned adhesive composition of the present invention.

Since this circuit connecting material contains the aforementioned adhesive composition of the present invention, this circuit connecting material has high adhesion strength even for an adherend composed of an inorganic material (circuit member, and the like), and for example, is suitable for connecting circuit members to each other. Furthermore, it is possible to obtain stable adhesion strength even under a high temperature and high humidity environment for long period of time.

Furthermore, the circuit connecting material of the present invention may further contain conductive particles. Since the circuit connecting material contains conductive particles, it is possible to improve connection reliability between electrodes to be connected (between circuit electrodes, and the like), and at the same time, reduce connection resistance.

A circuit member connecting structure of the present invention (in the present description, “connecting structure” is also referred to as “connecting structural body” or “connected member”) comprises a first circuit member having a first circuit electrode formed on a main surface of a first circuit board; a second circuit member having a second circuit electrode formed on a main surface of a second circuit board; and a circuit connecting member which is formed between the main surface of the first circuit board and the main surface of the second circuit board and connects the first circuit member and the second circuit member in the condition in which the first circuit electrode and the second circuit electrode are arranged facing each other, wherein the circuit connecting member is composed of a cured material of the circuit connecting material of the present invention, and the first circuit electrode and the second circuit electrode are electrically connected to each other.

Since the circuit member connecting structure comprises the circuit connecting member composed of a cured material of the circuit connecting material of the present invention, the circuit member connecting structure is excellent in reliability of the adhesion strength and obtain stable adhesion strength even under a high temperature and high humidity environment for long period of time. Especially, in the case where the circuit connecting material comprises the conductive particles, in addition to the aforementioned effect, the connection resistance is sufficiently reduced. Moreover, since the circuit connecting material of the present invention can obtain sufficient adhesion strength for an adherend composed of an inorganic material and obtain stable adhesion strength even under a high temperature and high humidity environment for long period of time, at least a part of an adherend surface (a surface to be connected via the connecting member) of the first circuit member or the second circuit member may be composed of an inorganic material.

In a method for manufacturing the circuit member connecting structure of the present invention, the circuit connecting material of the present invention is placed between the main surface of the first circuit board and the main surface of the second circuit board, and the circuit connecting material is heated and pressed to be cured (curing treatment) via the first and second circuit members, thereby connecting the first circuit member and the second circuit member, and electrically connecting the first circuit electrode and the second circuit electrode.

According to the method for manufacturing the circuit member connecting structure, it is possible to manufacture the circuit member connecting structure which is excellent in reliability of the adhesion strength and has stable adhesion strength even under a high temperature and high humidity environment for long period of time by using the circuit connecting material of the present invention. Moreover, in the case where the circuit connecting material comprises the radical polymerizable compound and the radical polymerization initiator, in addition to the aforementioned effect, low-temperature rapid curing can be achieved, thereby adverse effect on the circuit members can be sufficiently suppressed. Furthermore, since the circuit connecting material of the present invention can obtain sufficient adhesion strength even for an adherend composed of an inorganic material and obtain stable adhesion strength even under a high temperature and high humidity environment for long period of time, at least a part of an adherend surface of the first circuit member or the second circuit member may be composed of an inorganic material.

As mentioned above, the circuit connecting material of the present invention can be preferably used for connecting the first circuit member having a first circuit electrode formed on a main surface of a first circuit board and the second circuit member having a second circuit electrode formed on a main surface of a second circuit board in the condition in which the first circuit electrode and the second circuit electrode are arranged facing each other. In this case, at least a part of an adherend surface of the first circuit member or the second circuit member may be composed of an inorganic material.

A solar cell module of the present invention comprises a solar cell having an electrode; a wiring member; and a connecting member connecting the solar cell and the wiring member so that the electrode and the wiring member are electrically connected to each other, wherein the connecting member is composed of a cured material of the circuit connecting material of the present invention.

Since the solar cell module comprises the connecting member composed of a cured material of the circuit connecting material of the present invention, the solar cell module is excellent in reliability of the adhesion strength and obtain stable adhesion strength even under a high temperature and high humidity environment for long period of time. Especially, in the case where the circuit connecting material comprises the conductive particles, in addition to the aforementioned effect, the connection resistance is sufficiently reduced. Furthermore, in the case where the circuit connecting material comprises the radical polymerizable compound and the radical polymerization initiator as the curable component (C), low-temperature rapid curing can be achieved, thereby it is possible to manufacture the solar cell module without deteriorating the solar cell at the time of connection, which offers a solar cell module having higher reliability in comparison with the conventional techniques.

As mentioned above, the circuit connecting material of the present invention can be preferably used also for connecting the solar cell having an electrode and the wiring member so that the electrode and the wiring member are electrically connected to each other.

### Effects of the Invention

The adhesive composition of the present invention can provide sufficient adhesion strength even for an adherend composed of an inorganic material and provide stable adhesion strength even under a high temperature and high humidity environment for a long period of time.

Moreover, the film-like adhesive of the present invention is easy to handle, can be placed on the adherend such as a board easily, and connecting operations can be conducted easily.

Furthermore, the circuit connecting material of the present invention is suitable for bonding a circuit member (for example, a semiconductor device or a liquid crystal display device). Moreover, the circuit member connecting structure manufactured by using the circuit connecting material containing the conductive particles has sufficiently reduced connection resistance and excellent in reliability of the adhesion strength (especially under a high temperature and high humidity environment). Furthermore, in the case where the circuit connecting material is one comprising the radical polymerizable compound and the radical polymerization initiator, according to the method for manufacturing the circuit member connecting structure using the circuit connecting material, low-temperature rapid curing can be achieved, thereby adverse effect on the circuit members is sufficiently suppressed.

### BRIEF DESCRIPTION OF DRAWINGS

FIG. 1 is a schematic cross sectional view illustrating one embodiment of a film-like adhesive;

FIG. 2 is a schematic cross sectional view illustrating one embodiment of a circuit member connecting structure;

FIG. 3 (a) to (c) are each a series of process diagrams for connection of circuit members; and

FIG. 4 is a schematic cross sectional view illustrating one embodiment of a solar cell module.

### EMBODIMENTS FOR CARRYING OUT THE INVENTION

Hereinafter, a detailed description will be given of preferred embodiments of the present invention with reference to the drawings as required. It is noted that in the following description, the same or corresponding parts are denoted by the same reference numerals and the overlapping description will be omitted. Moreover, in the following description, (meth)acrylate means acrylate or the corresponding methacrylate.

[Adhesive Composition]

An adhesive composition of the present invention contains a curable component (C), an organoaluminum complex (A), and a silane coupling agent (B).

The curable component (C) in the present invention is a component having the property of being cured by external energy such as heat or energy lines. The curable component is not particularly limited, but for example, may be one comprising a combination of a radical polymerizable compound and a radical polymerization initiator. By comprising a radical polymerizable compound, low-temperature rapid curing can be achieved.

The radical polymerizable compound is a substance having a functional group which is polymerized by a radical. Examples of the radical polymerizable compound include (meth)acrylate, a maleimide compound, and a styrene derivative. These can be used alone or as a mixture of two or more. The radical polymerizable compound can be used in either form of a monomer or an oligomer, and the monomer and the oligomer may be used after mixed with each other.

Examples of the (meth)acrylate compound include methyl(meta)acrylate, ethyl(meta)acrylate, isopropyl(meta)acrylate, isobutyl(meta)acrylate, ethylene glycol di(meta)acrylate, diethylene glycol di(meta)acrylate, trimethylolpropane tri(meta)acrylate, tetramethylene glycol tetra(meta)acrylate, 2-hydroxy-1,3-diacryloxypropane, 2,2-bis[4-(acryloxymethoxy)phenyl]propane, 2,2-bis[4-(acryloxyethoxy)phenyl]propane, dicyclopentenyl(meta)acrylate tricyclodecanyl(meta)acrylate, tris(acryloxyethyl)isocyanurate, urethane(meta)acrylate, and isocyanuric acid ethylene oxide-modified diacrylate. These can be used alone or as a mixture of two or more. By radical polymerizing the (meth)acrylate compound, a (meth)acrylic resin is obtained.

The maleimide compound is a compound having at least one maleimide group. Examples of the maleimide compound include phenyl maleimide, 1-methyl-2,4-bismaleimide benzene, N,N′-m-phenylene bismaleimide, N,N′-p-phenylene bismaleimide, N,N′-4,4-biphenylene bismaleimide, N,N′-4,4-(3,3-dimethyl biphenylene)bismaleimide, N,N′-4,4-(3,3-dimethyl diphenyl methane)bismaleimide, N,N′-4,4-(3,3-diethyl diphenyl methane)bismaleimide, N,N′-4,4-diphenyl methane bismaleimide, N,N′-4,4-diphenyl propane bismaleimide, N,N′-4,4-diphenyl ether bismaleimide, N,N′-4,4-diphenyl sulfone bismaleimide, 2,2-bis(4-(4-maleimide phenoxy)phenyl)propane, 2,2-bis(3-s-butyl-3,4-(4-maleimide phenoxy)phenyl)propane, 1,1-bis(4-(4-maleimide phenoxy)phenyl)decane, 4,4′-cyclohexylidene-bis(1-(4-maleimide phenoxy)phenoxy)-2-cyclohexyl benzene, and 2,2-bis(4-(4-maleimide phenoxy)phenyl)hexafluoropropane. These can be used alone or as a mixture of two or more.

The styrene derivative is a compound in which a hydrogen atom at an α-position or on an aromatic ring in styrene is substituted by a substituent group.

Examples of the radical polymerization initiator include a compound which is decomposed by heat to generate a free radical, such as a peroxide compound, and an azo compound. While these are arbitrarily selected depending on the intended connection temperature, connection time, storage stability, or the like, in view of high reactivity and storage stability, an organic peroxide compound or an azo compound having a 10-hour half-life temperature of 40° C. or more and having a 1-minute half-life temperature of 180° C. or less is preferred, and an organic peroxide compound or an azo compound having a 10-hour half-life temperature of 60° C. or more and having a 1-minute half-life temperature of 170° C. or less is more preferred. In the case where the connection time is set to 10 seconds or less, a blending amount of the radical polymerization initiator is preferably 0.1 to 40 mass parts, more preferably 0.1 to 30 mass parts with respect to 100 mass parts of the radical polymerizable compound for the purpose of obtaining sufficient reaction rate. When the blending amount of the radical polymerization initiator is less than 0.1 mass parts, sufficient reaction rate cannot be obtained, and there is a tendency that satisfactory adhesion strength or a low connection resistance is hard to be obtained. On the other hand, the blending amount of the radical polymerization initiator exceeds 40 mass parts, there is a tendency that fluidity of the adhesive decreases, the connection resistance increases, or the storage stability decreases.

Specific examples of the radical polymerization initiator include diacyl peroxide, peroxydicarbonate, peroxyester, peroxyketal, dialkyl peroxide, hydroperoxide and silyl peroxide. Moreover, for suppressing corrosion at a connection terminal of a circuit member, it is preferred that a chlorine ion or an organic acid contained in the radical polymerization initiator is 5000 ppm or less. Among these, it is preferred that the radical polymerization initiator is selected from peroxyester, peroxyketal, dialkyl peroxide, hydroperoxide or silyl peroxide, and is more preferred that the radical polymerization initiator is selected from peroxyester or peroxyketal because high reactivity can be obtained. These can be used alone or as a mixture of two or more.

Examples of the diacyl peroxide include isobutyl peroxide, 2,4-dichlorobenzoyl peroxide, 3,5,5-trimethyl hexanoyl peroxide, octanoyl peroxide, lauroyl peroxide, stearoyl peroxide, succinic peroxide, benzoyl peroxytoluene, and benzoyl peroxide.

Examples of the peroxydicarbonate include di-n-propyl peroxydicarbonate, diisopropyl peroxydicarbonate, bis(4-t-butylcyclohexyl)peroxydicarbonate, di-2-ethoxymethoxyperoxydicarbonate, di(2-ethylhexylperoxy)dicarbonate, dimethoxybutyl peroxydicarbonate, and di(3-methyl-3-methoxybutyl peroxy)dicarbonate.

Examples of the peroxyester include cumyl peroxyneodecanoate, 1,1,3,3-tetramethyl butyl peroxyneodecanoate, 1-cyclohexyl-1-methylethyl peroxynoedecanoate, t-hexyl peroxyneodecanoate, t-butyl peroxypivalate, 1,1,3,3-tetramethyl butyl peroxy-2-ethylhexanoate, 2,5-dimethyl-2,5-di(2-ethyl hexanoyl peroxy)hexane, 1-cyclohexyl-1-methyl ethyl peroxy-2-ethylhexanoate, t-hexylperoxy-2-ethylhexanoate, t-butyl peroxy-2-ethylhexanoate, t-butyl peroxyisobutyrate, 1,1-bis(t-butyl peroxy)cyclohexane, t-hexylperoxy isopropyl monocarbonate, t-butyl peroxy-3,5,5-trimethyl hexanoate, t-butyl peroxylaurate, 2,5-dimethyl-2,5-di(m-toluoyl peroxy)hexane, t-butyl peroxyisopropyl monocarbonate, t-butyl peroxy-2-ethylhexyl monocarbonate, t-hexyl peroxybenzoate, and t-butyl peroxyacetate.

Examples of the peroxyketal include 1,1-bis(t-hexylperoxy)-3,3,5-trimethyl cyclohexane, 1,1-bis(t-hexylperoxy)cyclohexane, 1,1-bis(t-butyl peroxy)-3,3,5-trimethyl cyclohexane, 1,1-(t-butyl peroxy)cyclododecane, and 2,2-bis(t-butyl peroxy)decane.

Examples of the dialkyl peroxide include α,α′-bis(t-butyl peroxy)diisopropylbenzene, dicumyl peroxide, 2,5-dimethyl-2,5-di(t-butyl peroxy)hexane, and t-butyl cumyl peroxide.

Examples of the hydroperoxide include diisopropylbenzene hydroperoxide and cumene hydroperoxide.

Examples of the silyl peroxide include t-butyl trimethyl silyl peroxide, bis(t-butyl)dimethyl silyl peroxide, t-butyl trivinyl silyl peroxide, bis(t-butyl)divinyl silyl peroxide, tris(t-butyl)vinyl silyl peroxide, t-butyl triallyl silyl peroxide, bis(t-butyl)diallyl silyl peroxide, and tris(t-butyl)allyl silyl peroxide.

These radical polymerization initiators which generate a free radical by heat can be used alone or as a mixture thereof, and further, may be used after mixed with a decomposition accelerator, an inhibitor, or the like. Furthermore, one which is microencapsulated by covering these initiators with a polyurethane based or polyester based high molecular substance, or the like is preferred because an usable time is extended.

A content of the curable component (C) in the adhesive composition is not particularly limited, but for example, can be 10 to 95 mass % with respect to a total amount of the adhesive composition. Furthermore, in view of reducing the connection resistance, the content of the curable component (C) is preferably 30 to 80 mass %, more preferably 40 to 60 mass %.

The organoaluminum complex (A) is a molecule in which a ligand composed of an organic group binds to aluminum. The bond between aluminum and the ligand may be either a hydrogen bond or a coordination bond. The organic group just has to be a group composed of a carbon atom, a hydrogen atom, and an oxygen atom, and may further contain a sulfur atom, a nitrogen atom, or the like.

The organoaluminum complex (A) may be one having a structure in which an alkoxy anion, a conjugated anion of β-diketone, or a conjugated anion of β-ketoester binds to a trivalent aluminum cation as a ligand, which is represented by formula (1):

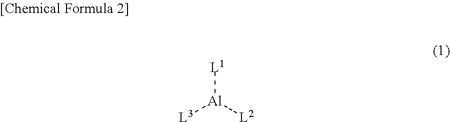

wherein, L¹, L², and L³ each independently represent an alkoxy anion, a conjugated anion of β-diketone, or a conjugated anion of β-ketoester; and L¹, L², and L³ may be the same or different from each other.

Specific examples of the organoaluminum complex represented by formula (1) include aluminium tris(acetyl acetonate), aluminium tris(ethyl acetoacetate), aluminium monoacetyl acetonate bis(ethyl acetoacetate), aluminium monoacetyl acetonate bisoleyl acetoacetate, ethyl acetoacetate aluminum diisopropylate, and alkyl acetoacetate aluminum diisopropylate.

A content of the organoaluminum complex (A) in the adhesive composition is not particularly limited, but for example, can be 0.01 to 30 mass parts with respect to 100 mass parts of the curable component (C). Furthermore, in view of improving the adhesion force, the content of the organoaluminum complex (A) is preferably 1 to 10 mass parts, more preferably 1 to 5 mass parts.

The silane coupling agent is a compound having an organic functional group and a hydrolysable group in its molecule, and examples thereof include a vinyl group-containing silane coupling agent, an epoxy group-containing silane coupling agent, a styryl group-containing silane coupling agent, a methacryl group-containing silane coupling agent, an acryl group-containing silane coupling agent, an amino group-containing silane coupling agent, an ureido group-containing silane coupling agent, a mercapto group-containing silane coupling agent, a sulfide group-containing silane coupling agent, an isocyanate group-containing silane coupling agent, and an allyl group-containing silane coupling agent. Among these, in view of improving the adhesion force, a methacryl group-containing silane coupling agent or an acryl group-containing silane coupling agent is preferred.

Examples of the hydrolysable group include an alkoxy group having 1 to 6 carbon atoms such as a methoxy group and ethoxy group, an acetoxy group, and 2-methoxyethoxy group.

Examples of the vinyl group-containing silane coupling agent include vinyltrimethoxysilane, vinyltriethoxysilane, vinyltris(2-methoxyethoxy)silane, vinylmethyldimethoxysilane, and vinyltriacetoxysilane.

Examples of the epoxy group-containing silane coupling agent include 2-(3,4-epoxycyclohexyl)ethyl trimethoxysilane, 3-glycidoxypropyl methyl dimethoxysilane, 3-glycidoxypropyl trimethoxysilane, 3-glycidoxypropyl methyl diethoxysilane, and 3-glycidoxypropyl triethoxysilane.

Examples of the styryl group-containing silane coupling agent include p-styryltrimethoxysilane.

Examples of the methacryl group-containing silane coupling agent include 3-methacryloxypropyl methyl dimethoxysilane, 3-methacryloxypropyl trimethoxysilane, 3-methacryloxypropyl methyl diethoxysilane, and 3-methacryloxypropyl triethoxysilane.

Examples of the acryl group-containing silane coupling agent include 3-acryloxypropyltrimethoxysilane.

Examples of the amino group-containing silane coupling agent include N-2-(aminoethyl)-3-aminopropyl methyl dimethoxysilane, N-2-(aminoethyl)-3-aminopropyl trimethoxysilane, N-2-(aminoethyl)-3-aminopropyltriethoxysilane, 3-aminopropyl trimethoxysilane, 3-aminopropyltriethoxysilane, 3-triethoxysilyl-N-(1,3-dimethyl-butylidene)propylamine, N-phenyl-3-aminopropyl trimethoxysilane, and N-(vinyl benzyl)-2-aminoethyl-3-aminopropyl trimethoxysilane.

Examples of the ureido group-containing silane coupling agent include 3-ureidopropyltriethoxysilane.

Examples of the mercapto group-containing silane coupling agent include 3-mercaptopropylmethyldimethoxysilane, 3-mercaptopropyltrimethoxysilane, and 3-mercaptopropyltriethoxysilane.

Examples of the sulfide group-containing silane coupling agent include bis(triethoxysilylpropyl)tetrasulfide.

Examples of the isocyanate group-containing silane coupling agent include 3-isocyanatepropyltriethoxysilane and 3-isocyanatepropyltrimethoxysilane.

Examples of the allyl group-containing silane coupling agent include allyltrimethoxysilane.

A content of the silane coupling agent (B) in the adhesive composition is not particularly limited, but for example, can be 0.01 to 30 mass parts with respect to 100 mass parts of the curable component (C). Furthermore, in view of improving the adhesion force, the content of the silane coupling agent (B) is preferably 0.1 to 10 mass parts, more preferably 0.1 to 5 mass parts.

The adhesive composition of the present invention may contain a film forming material in addition to the curable component, the organoaluminum complex, and the silane coupling agent described above.

The film forming material is a material which, when a liquid substance is solidified and a composition is formed into a film shape, confers mechanical properties that facilitate handling of the film, prevent easy tearing, cracking or sticking on the film, thereby permitting it to be handled as a film under ordinary conditions. Examples of the film forming material include a phenoxy resin, a polyvinyl formal resin, a polystyrene resin, a polyvinyl butyral resin, a polyester resin, a polyamide resin, a xylene resin, and a polyurethane resin. Among these, preferred is a phenoxy resin because this resin is excellent in the adhesion strength, compatibility, heat resistance, and mechanical strength.

The phenoxy resin is a resin which is obtained by reacting a bifunctional phenol with an epihalohydrin until a high molecular weight is achieved, or by polyaddition of a bifunctional epoxy resin and a bifunctional phenol. Specifically, the phenoxy resin is obtained by reacting 1 mole of a bifunctional phenol with 0.985 to 1.015 moles of an epihalohydrin in a nonreactive solvent at a temperature of 40 to 120° C. in the presence of an alkali metal hydroxide. Moreover, in view of mechanical properties and thermal properties of the resin, especially preferred is one obtained by polyaddition reaction of a bifunctional epoxy resin and a bifunctional phenol at an epoxy group/phenol hydroxyl group equivalent ratio of 1/0.9 to 1/1.1, with heating to 50 to 200° C. in the presence of a catalyst such as an alkali metal compound, an organic phosphorus-based compound, and a cyclic amine-based compound in such as an amide-based, ether-based, ketone-based, lactone-based, or alcohol-based organic solvent having a boiling point of 120° C. or higher under the conditions that a reaction solid content is 50 mass parts or less.

Examples of the bifunctional epoxy resin include a bisphenol A-type epoxy resin, a bisphenol F-type epoxy resin, a bisphenol AD-type epoxy resin, a bisphenol S-type epoxy resin, biphenyl diglycidyl ether, and methyl-substituted biphenyl diglycidyl ether.

The bifunctional phenol is a compound having two phenolic hydroxyl groups, and examples thereof include hydroquinones, and bisphenols such as bisphenol A, bisphenol F, bisphenol AD, bisphenol S, bisphenolfluorene, methyl-substituted bisphenolfluorene, dihydroxybiphenyl and methyl-substituted dihydroxybiphenyl.

Furthermore, the phenoxy resin may be modified with a radical-polymerizable functional group or another reactive compound. The phenoxy resins may be used alone or as a mixture of two or more.

A content of the film forming material in the adhesive composition is not particularly limited, but for example, is preferably 20 to 70 mass parts, more preferably 40 to 60 mass parts with respect to 100 mass parts of the curable component (C).

In the case where the adhesive composition contains the film forming material, the radical polymerizable compound, and the radical polymerization initiator, it is preferred that a mixed ratio of the silane coupling agent is 0.01 to 25 mass parts with respect to 100 mass parts of a total of the film forming material, the radical polymerizable compound, and the radical polymerization initiator in view of improving the adhesion strength of the adhesive composition. Furthermore, the mixed ratio of the silane coupling agent is more preferably 0.1 to 20 mass parts, still more preferably 0.5 to 15 mass parts, most preferably 1 to 10 mass parts.

In the adhesive composition of the present invention, further a polymer or a copolymer comprising at least one of acrylic acid, acrylic acid ester, methacrylic acid ester, and acrylonitrile as a monomer component can be blended. Especially, the case where an acrylic rubber based on a copolymer containing glycidyl acrylate or glycidyl methacrylate having a glycidyl ether group is used concurrently is preferred because, if so, a high degree of stress relaxation is achieved. It is preferred that a weigh average molecular weight of the acrylic rubber is 200,000 or more in view of increasing cohesion of the adhesive composition.

Furthermore, in the adhesive composition of the present invention, further a filler, a softening agent, an accelerator, an antioxidant, a flame retardant, a pigment, a thixotropic agent, a phenol resin, a melamine resin, an isocyanate, or the like can be blended.

Form of use of the adhesive composition having the composition described above is not particularly limited, but for example, it is possible to use the adhesive composition as a solution prepared by dissolving and/or dispersing the aforementioned components in an organic solvent such as toluene and ethyl acetate or as a formed body prepared by removing the solvent from the solution and forming it into a prescribed shape (for example, a film-like adhesive described below).

[Circuit Connecting Material]

A circuit connecting material of the present invention contains the aforementioned adhesive composition. Furthermore, the circuit connecting material may contain conductive particles.

Examples of the conductive particles include metal particles containing Au, Ag, Ni, Cu, solder, or the like, and carbon particles. In view of achieving sufficient storage stability, a surface layer of the conductive particles is preferably not composed of a transition metal such as Ni or Cu, but of a noble metal such as Au, Ag, or a platinum group metal, and more preferably composed of Au. The conductive particles may be those having a surface of a transition metal such as Ni covered with a noble metal such as Au. Furthermore, as the conductive particles, complex particles prepared by covering non-conductive glass, ceramic, plastic, or the like with a conductive substance such as metals descried above can be used, and also in this case, those having an outermost layer composed of a noble metal is preferred. The conductive particles may be, for example, those prepared by covering metal particles composed of copper with silver. Furthermore, as the conductive particles, a metal powder having a configuration in which a plurality of fine metal particles links to each other in chains as described in Japanese Patent Application Laid-Open 2005-116291 can be used.

The case where particles prepared by covering non-conductive plastic or the like with a conductive substance, or heat-fusible metallic particles are used as the conductive particles is preferred because, if so, these conductive particles are deformed by heat and pressure, and then, there is a tendency that a contact area with an electrode increases at the time of connection and variation in thickness of the circuit terminal of the circuit member is absorbed, thereby the connection reliability is improved.

A thickness of the covering layer composed of the noble metal is preferably 10 nm or more in view of achieving satisfactory resistance. However, when the layer composed of the noble metal is formed on the transition metal such as Ni, there is a tendency that a free radical is generated by redox action caused by defect of the noble metal layer, defect of the noble metal layer caused during mixing and dispersion of the conductive particles, or the like, which leads to a decrease in the storage stability, and therefore, in view of preventing this, the thickness of the covering layer is preferably 30 nm or more. It is noted that an upper limit of the thickness of the covering layer is not particularly limited, but is preferably 1 μm or less because the obtained effect becomes saturated.

Alternatively, as the conductive particles, particles prepared by covering the surface of the aforementioned conductive particles with insulating particles, or particles prepared by forming an insulating layer composed of an insulating material on the surface of the aforementioned conductive particles by a hybridization method, or the like can be used. By using such conductive particles, a short circuit caused by contact between the adjacent conductive particles is not likely to occur.

It is preferred that an average particle diameter of the conductive particles is 1 to 20 μm. The average particle diameter of the conductive particles can be measured by using a particle size distribution measuring device (for example, LS13 320 manufactured by Beckman Coulter, Inc).

A blending amount of the conductive particles is preferably 0.1 to 30 volume parts with respect to 100 volume parts of the adhesive composition, and it is preferred that the blending amount is arbitrarily controlled in this range depending on the purpose. It is noted that the blending amount is more preferably 0.1 to 10 volume parts in view of preventing the short circuit between the adjacent circuits or the like caused by the conductive particles being present excessively.

The aforementioned circuit connecting material can be preferably used for the connection between circuits, and the connection between a circuit and a conductive member such as a wiring member. For example, the aforementioned circuit connecting material is suitable for use for connecting a first circuit member having a first circuit electrode formed on a main surface of a first circuit board and a second circuit member having a second circuit electrode formed on a main surface of a second circuit board in the condition that the first circuit electrode and the second circuit electrode are arranged facing each other, or use for connecting a solar cell having an electrode and a wiring member so that the electrode and the wiring member are electrically connected to each other.

[Film-Like Adhesive]

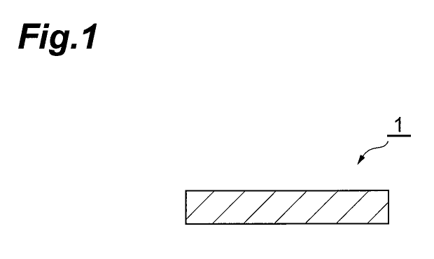

FIG. 1 is a schematic cross sectional view illustrating one embodiment of a film-like adhesive. A film-like adhesive 1 shown in FIG. 1 is one prepared by forming the aforementioned adhesive composition into a film shape. The film-like adhesive 1 is easy to handle, can be placed on an adherend easily, and connecting operations can be conducted easily.

It is noted that the film-like adhesive 1 may have a multilayered structure (not shown) consisting of two or more layers which have different Tg (grass transition temperature) by 5° C. or more, the Tg being a grass transition temperature of the adhesive composition after cured.

For example, the film-like adhesive 1 can be produced by applying a solution prepared by dissolving the adhesive composition in a solvent on a support (PET (polyethylene terephthalate) film, or the like) using a coater, and then, performing hot-air drying for a prescribed time at such a temperature that the adhesive composition is not cured. Moreover, a thickness of the film-like adhesive 1 can be, for example, 10 to 50 μm.

[Circuit Member Connecting Structure]

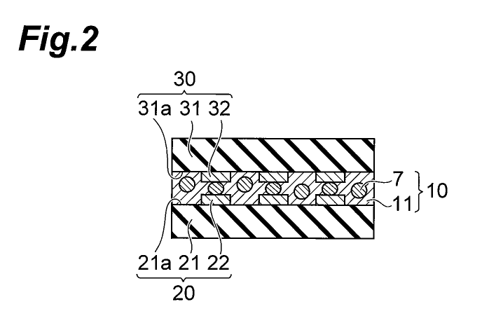

FIG. 2 is a schematic cross sectional view illustrating one embodiment of a circuit member connecting structure. As shown in FIG. 2, the circuit member connecting structure of the present embodiment comprises a first circuit member 20 and a second circuit member 30 facing each other, and between the first circuit member 20 and the second circuit member 30, comprises a circuit connecting member 10 connecting these members. The first circuit member 20 or the second circuit member 30 may be composed of an inorganic material. Moreover, at least a part of an adherend surface with the connecting member may be composed of an inorganic material.

The first circuit member 20 comprises a circuit board (first circuit board) 21 and a circuit electrode (first circuit electrode) 22 formed on a main surface 21a of the circuit board 21. It is noted that an insulating layer (not shown) may be formed on the main surface 21a of the circuit board 21 depending on the case.

On the other hand, the second circuit member 30 comprises a circuit board (second circuit board) 31 and a circuit electrode (second circuit electrode) 32 formed on a main surface 31a of the circuit board 31. Also, an insulating layer (not shown) may be formed on the main surface 31a of the circuit board 31 depending on the case.

The first circuit member 20 and the second circuit member 30 are not particularly limited so far as an electrode requiring electrical connection is formed thereon. Specific examples thereof include a glass or plastic board on which an electrode is formed by using ITO and the like which is used in a liquid crystal display, a printed wiring board, a ceramic wiring board, a flexible wiring board, and a semiconductor silicon chip, and these are used in combination as required. As just described, in the present embodiment, it is possible to use a printed circuit board, or a circuit member having a wide variety of surface conditions including a material composed of an inorganic material such as a metal including copper and aluminum, ITO (indiumtin oxide), silicon nitride (SiNX), and silicon dioxide (SiO₂), as well as a material composed of an organic material such as polyimide.

The circuit connecting member 10 contains an insulating material 11 and conductive particles 7. The conductive particles 7 are provided not only between the circuit electrode 22 and the circuit electrode 32 facing each other, but also between the main surface 21a and the main surface 31a. In the circuit member connecting structure, the circuit electrode 22 and the circuit electrode 32 are electrically connected to each other via the conductive particles 7. That is, the conductive particles 7 have contact with both of the circuit electrode 22 and the circuit electrode 32 directly.

Here, the conductive particles 7 are not particularly limited so far as they have such conductivity that the electrical connection is obtained, but examples thereof include metal particles such as Au, Ag, Ni, Cu, Co, and solder, and carbon. Also, those prepared by covering non-conductive glass, ceramics, plastic, or the like with a conductive material such as the aforementioned metal can be used. In this case, a thickness of a covering metal layer is preferably 10 nm or more in view of obtaining sufficient conductivity.

In the circuit member connecting structure, the circuit electrode 22 and the circuit electrode 32 facing each other are electrically connected to each other via the conductive particles 7, as described above. Therefore, the connection resistance between the circuit electrode 22 and the circuit electrode 32 is sufficiently reduced. This allows flow of an electric current between the circuit electrode 22 and the circuit electrode 32 to run smoothly, thereby it is possible to exert the function of the circuit sufficiently. It is noted that, when the circuit connecting member 10 does not contain the conductive particles 7, the circuit electrode 22 and the circuit electrode 32 are electrically connected to each other by having contact with each other directly.

Since the circuit connecting member 10 is composed of a cured material of the circuit connecting material containing the adhesive composition as described below, the adhesion strength of the circuit connecting member 10 for the first circuit member 20 or the second circuit member 30 becomes sufficiently high, and stable adhesion strength can be obtained especially under a high temperature and high humidity environment. Moreover, in the circuit member connecting structure, a condition in which the adhesion strength is sufficiently high is maintained for long period of time. Therefore, change in distance between the circuit electrode 22 and the circuit electrode 32 over time is sufficiently prevented, and it is possible to sufficiently improve the long-term reliability of electrical properties between the circuit electrode 22 and the circuit electrode 32.

[Method for Manufacturing Circuit Member Connecting Structure]

Next, a description will be given of a method for manufacturing the aforementioned circuit member connecting structure.

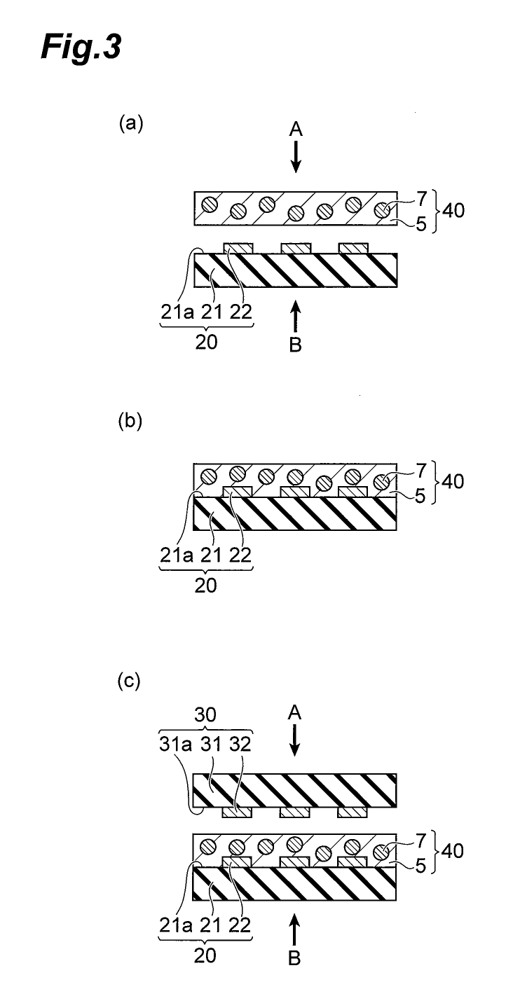

First, the first circuit member 20 described above and a film-like circuit connecting material 40 are prepared (see FIG. 3(a)). The film-like circuit connecting material 40 is a material prepared by forming the circuit connecting material into a film shape. The circuit connecting material contains an adhesive composition 5 and conductive particles 7. Here, as the adhesive composition 5, the aforementioned adhesive composition of the present invention is used. In the following description, a case in which the curable component in the adhesive composition 5 is the radical polymerizable compound and the radical polymerization initiator will be described. It is noted that, even in the case where the circuit connecting material does not contain the conductive particles 7, such a circuit connecting material can be used for anisotropic conductive adhesion as an insulating adhesive, which is especially called NCP (Non-Conductive Paste) in some cases. In the case where the circuit connecting material contains the conductive particles 7, such a circuit connecting material is called ACP (Anisotropic Conductive Paste) in some cases.

A thickness of the film-like circuit connecting material 40 is preferably 10 to 50 μm. When the thickness of the film-like circuit connecting material 40 is less than 10 μm, there is a tendency that the circuit connecting material poorly fills the area between the circuit electrode 22 and the circuit electrode 32. On the other hand, when the thickness of the film-like circuit connecting material 40 exceeds 50 μm, it becomes difficult to sufficiently remove the adhesive composition between the circuit electrode 22 and the circuit electrode 32, and there is a tendency that ensuring of conduction between the circuit electrode 22 and the circuit electrode 32 becomes difficult.

Next, the film-like circuit connecting material 40 is placed on the first circuit member 20 on a surface having the circuit electrode 22 formed thereon. It is noted that, in the case where the film-like circuit connecting material 40 adheres onto a support (not shown), it is placed on the first circuit member 20 with orienting the film-like circuit connecting material 40 side toward the first circuit member 20. In this case, the film-like circuit connecting material 40 has a film shape, and its handling is easy. Therefore, it is possible to easily place the film-like circuit connecting material 40 between the first circuit member 20 and the second circuit member 30, and easily conduct connecting operations between the first circuit member 20 and the second circuit member 30.

Then, the film-like circuit connecting material 40 is pressed in the direction of the arrows A and B in FIG. 3(a) to temporarily connect the film-like circuit connecting material 40 to the first circuit member 20 (see FIG. 3(b)). At this time, the film-like circuit connecting material 40 may be pressed with heating. It should be noted that the heating temperature is set to a temperature at which the adhesive composition in the film-like circuit connecting material 40 is not cured, that is, a temperature which is lower than the temperature at which the radical polymerization initiator generates a radical.

Next, as shown in FIG. 3(c), the second circuit member 30 is placed on the film-like circuit connecting material 40 with orienting the second circuit electrode 32 toward the first circuit member 20 (that is, in the condition in which the first circuit electrode 22 and the second circuit electrode 32 are arranged facing each other). It is noted that, in the case where the film-like circuit connecting material 40 adheres onto a support (not shown), the second circuit member 30 is placed on the film-like circuit connecting material 40 after the support is peeled off.

Then, the film-like circuit connecting material 40 is pressed with heating in the direction of the arrows A and B in FIG. 3(c) via the first circuit member 20 and the second circuit member 30. The heating temperature at this time is set to a temperature at which the radical polymerization initiator can generate a radical. By this, a radical is generated by the radical polymerization initiator, and then, polymerization of the radical polymerizable compound starts. Thus, the film-like circuit connecting material 40 is subjected to curing treatment and permanent connection is conducted, and then, the circuit member connecting structure shown in FIG. 2 is obtained.

The heating temperature is, for example, 90 to 200° C., and the connection time is, for example, 1 second to 10 minutes. These conditions are arbitrarily selected depending on the use purpose, the adhesive composition, and the circuit member, and post-curing may be conducted as needed. For example, in the case where the curable component in the adhesive composition 5 is the radical polymerizable compound and the radical polymerization initiator as in the present embodiment, low-temperature rapid curing can also be achieved by setting the heating temperature to 100 to 170° C. and the connection time to 10 seconds or less.

When the circuit member connecting structure is manufactured as described above, it is possible to allow the conductive particles 7 to have contact with both of the circuit electrode 22 and the circuit electrode 32 facing each other in the obtained circuit member connecting structure, and sufficiently reduce the connection resistance between the circuit electrode 22 and the circuit electrode 32.

By the heating of the film-like circuit connecting material 40, the adhesive composition 5 is cured to become the insulating material 11 in the condition in which the distance between the circuit electrode 22 and the circuit electrode 32 is sufficiently small, and the first circuit member 20 and the second circuit member 30 are strongly connected to each other via the circuit connecting member 10. That is, in the obtained circuit member connecting structure, the circuit connecting member 10 is composed of a cured material of the circuit connecting material comprising the adhesive composition, and therefore, the adhesion strength of the circuit connecting member 10 for the first circuit member 20 or the second circuit member 30 is sufficiently high, and the adhesion strength is sufficiently high especially in high temperature and high humidity conditions. Moreover, in the circuit member connecting structure, a condition in which the adhesion strength is sufficiently high is maintained for long period of time. Therefore, in the obtained circuit member connecting structure, change in distance between the circuit electrode 22 and the circuit electrode 32 over time is sufficiently prevented and the long-term reliability of electrical properties between the circuit electrode 22 and the circuit electrode 32 is excellent.

It is noted that, while a composition comprising the radical polymerization initiator which generates a radical by at least heat is used as the adhesive composition 5 in the above embodiment, a radical polymerization initiator which generates a radical by light irradiation alone may be used instead of this radical polymerization initiator. In this case, at the time of curing treatment of the film-like circuit connecting material 40, light irradiation may be conducted instead of heating. Other than this, a radical polymerization initiator which generates a radical by ultrasonic waves, electromagnetic rays, or the like may be used as needed. Moreover, as the curable component in the adhesive composition 5, an epoxy resin and a latent hardener may be used.

Alternatively, while the circuit member connecting structure is manufactured by using the film-like circuit connecting material 40 in the above embodiment, a circuit connecting material which is not formed into a film shape may be used instead of the film-like circuit connecting material 40. Also in this case, the circuit connecting material is dissolved in a solvent, and the obtained solution is applied onto either the first circuit member 20 or the second circuit member 30 to be dried, thereby the circuit connecting material can be provided between the first circuit member 20 and the second circuit member 30.

Alternatively, other conductive materials may be used instead of the conductive particles 7. Examples of the other conductive materials include particulate or short fibrous carbon and a metal filament such as an Au plated Ni wire.

[Solar Cell Module]

The adhesive composition and the circuit connecting material of the present invention are preferably used also for a solar cell module in which a plurality of solar cells is electrically connected. Hereinafter, a description will be given of a solar cell module according to the present embodiment.

The solar cell module according to the present embodiment comprises a solar cell having an electrode, a wiring member, and a connecting member which connects the solar cell and the wiring member so that the electrode and the wiring member are electrically connected to each other. The connecting member contains a cured material of the circuit connecting material.

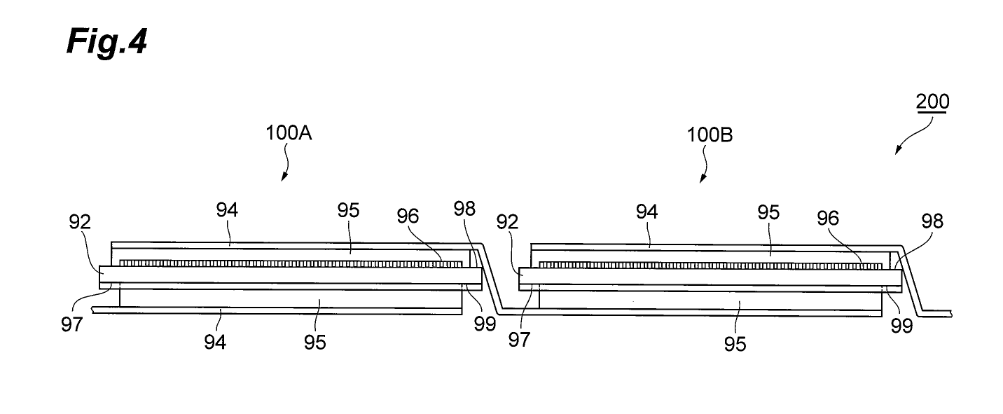

FIG. 4 is a schematic cross sectional view illustrating one embodiment of the solar cell module. As shown in FIG. 4, a solar cell module 200 comprises a solar cell 100A and a wiring member 94, and between the solar cell 100A and the wiring member 94, a connecting member 95 electrically connecting these members is provided.

The solar cell 100A has an electrode 96 on a board 92, and electrically connected to the wiring member 94 via the electrode 96. It is noted that a surface comprising the electrode 96 is a light receiving surface 98. In the solar cell 100A, a back surface electrode 97 is provided on a back surface 99 on the opposite side of the light receiving surface 98. The board 92 is, for example, composed of at least one of single crystal Si, multi crystal SI, and amorphous Si.

The wiring member 94 is a member for electrically connecting the solar cell 100A and another member. For example, in FIG. 4, the electrode 96 of the solar cell 100A and a back surface electrode 97 of a solar cell 100B are electrically connected to each other by the wiring member 94.

In the solar cell module 200 shown in FIG. 4, the wiring member 94 and the solar cell 100B are bonded by the connecting member 95 so that the wiring member 94 and the back surface electrode 97 of the solar cell 100B are electrically connected to each other.

The connecting member 95 may be, for example, one containing an insulating material and conductive particles. In the case where the connecting member 95 contains the conductive particles, the electrode 96 of the solar cell 100A and the wiring member 94 can be electrically connected via the conductive particles. Also, the back surface electrode 97 of the solar cell 100B and the wiring member 94 can be electrically connected via the conductive particles.

In the solar cell module 200 shown in FIG. 4, the connecting member 95 is composed of a cured material of the aforementioned circuit connecting material. By this, the adhesion strength of the connecting member 95 for the solar cell 100A and the wiring member 94 is sufficiently high, and at the same time, stable adhesion strength can be obtained even under a high temperature and high humidity environment for long period of time. Moreover, when the connecting member 95 contains the conductive particles, the connection resistance between the solar cell 100A and the wiring member 94 becomes sufficiently small. Furthermore, in the case where the circuit connecting material contains the radical polymerizable compound and the radical polymerization initiator as the curable component (C), the solar cell module 200 shown in FIG. 4 can be manufactured without deteriorating the solar cell 100A at the time of connection because the low-temperature rapid curing can be achieved, thereby can have higher reliability than those of the conventional techniques.

Furthermore, the solar cell module 200 shown in FIG. 4 can be manufactured by the same method as the method for manufacturing the circuit member connecting structure described above by using the solar cell 100A and the wiring member 94 as the first circuit member 20 and the second circuit member 30 in the method for manufacturing the circuit member connecting structure described above.

### EXAMPLES

Hereinafter, the present invention will be described in detail based on Examples and Comparative Examples, but the present invention is not limited to the following Examples.

### Example 1

Aluminum chelate D (product name by Kawaken Fine Chemicals Co., Ltd.) was used as the organoaluminum complex (A), 3-methacryloxypropyltrimethoxysilane SZ6030 (product name by Dow Corning Toray Co., Ltd) was used as the silane coupling agent (B), and UA5500 (product name by Negami Chemical Industrial Co., Ltd) and M313 (product name by Shin Nakamura Chemical Co., Ltd.) serving as the radical polymerizable compound and PEROYL L (product name by NOF Corporation) serving as the radical polymerization initiator were used as the curable component (C). A phenoxy resin (YP-70, product name by Tohto Kasei Co., Ltd) was used as a binder. Moreover, conductive particles having an average particle diameter of 3 μm and a specific weight of 2.5 were produced by forming a nickel layer having a thickness of 0.2 μm on a surface of particles containing polystyrene as a core, and then, forming a metal layer having a thickness of 0.02 μm on the outside of the nickel layer, and were used. The components were blended at a mixed ratio shown in Table 1, and then, applied onto a PET resin film having a thickness of 40 μm using a coater, and a film-like adhesive in which a thickness of an adhesive layer was 20 μm was obtained by hot-air drying at 70° C. for 5 minutes.

### Example 2

A film-like adhesive was obtained by the same method as that in Example 1 except that ALCH-TR (product name by Kawaken Fine Chemicals Co., Ltd.) was used as the organoaluminum complex (A). The mixed ratio of the components is shown in Table 1.

### Example 3

A film-like adhesive was obtained by the same method as that in Example 1 except that aluminum chelate A(W) (product name by Kawaken Fine Chemicals Co., Ltd.) was used as the organoaluminum complex (A). The mixed ratio of the components is shown in Table 1.

### Comparative Example 1

A film-like adhesive was obtained by the same method as that in Example 1 except that the organoaluminum complex (A) was not used. The mixed ratio of the components is shown in Table 1.

### Comparative Example 2

A film-like adhesive was obtained by the same method as that in Example 1 except that the silane coupling agent (B) was not used. The mixed ratio of the components is shown in Table 1.

### Comparative Example 3

A film-like adhesive was obtained by the same method as that in Example 1 except that the organoaluminum complex (A) was not used and an organic titanium complex (titaniumdiisopropoxidebis(acetylacetonate)) was used. The mixed ratio of the components is shown in Table 1.

TABLE 1

| | | | | | Comparative | | |
|---|---|---|---|---|---|---|---|
| | | Example | | | Example | | |
| | | 1 | 2 | 3 | 1 | 2 | 3 |
| Binder | YP-70 | 50 | 50 | 50 | 50 | 50 | 50 |
| Radical | UA5500 | 25 | 25 | 25 | 25 | 25 | 25 |
| polymerizable | M313 | 25 | 25 | 25 | 25 | 25 | 25 |
| compound | | | | | | | |
| Radical | PEROYL L | 5 | 5 | 5 | 5 | 5 | 5 |
| polymerization | | | | | | | |
| initiator | | | | | | | |
| Organic metal | Aluminum | 5 | — | — | — | 5 | — |
| complex | chelate D | | | | | | |
| | ALCH-TR | — | 5 | — | — | — | — |
| | Aluminum | — | — | 5 | — | — | — |
| | chelate A(W) | | | | | | |
| | Organic titanium | — | — | — | — | — | 5 |
| | complex | | | | | | |
| Silane coupling | SZ6030 | 5 | 5 | 5 | 5 | — | 5 |
| agent | | | | | | | |

| | | | | | | |
|---|---|---|---|---|---|---|
| Conductive particles | 30 | 30 | 30 | 30 | 30 | 30 |

In Table 1, each value represents a value expressed in terms of mass part except for the conductive particles. The value for the conductive particles represents a value expressed in terms of volume part with respect to 100 volume parts of the total of the components except for the conductive particles (adhesive composition).

[Manufacturing of Connected Member 1]

The film-like adhesive obtained by the method described above was transferred in a size of 2×20 mm to a glass board (corning #1737 having an outward form of 38 mm×28 mm, a thickness of 0.5 mm, and an ITO (indiumtin oxide) wiring pattern (pattern width 50 μm, pitch 50 μm) on its surface) from the PET resin film. An IC chip (outward form 1.7 mm×17.2 mm, thickness 0.55 mm, size of bump 50 μm×50 μm, pitch of bump 50 μm) was heated and pressed with applying a load of 80 MPa (converted value for the bump area) in the mounting conditions (temperature and time) shown in Table 2 to be mounted thereon. Moreover, also a film-like adhesive used for measurement of storage stability is mounted by the same method.

[Manufacturing of Connected Member 2]

The film-like adhesives of Examples 1 to 3 and Comparative Examples 1 to 3 each was transferred in a size of 2×15 mm to a glass board (corning #1737 having an outward form of 38 mm×28 mm and a thickness of 0.5 mm) from the PET resin film. An IC chip (outward form 1.0 mm×10 mm, thickness 0.55 mm, size of bump 50 μm×50 μm, pitch of bump 50 μm) was heated and pressed at 150° C. for 5 seconds with applying a load of 80 MPa (converted value for the bump area) to be mounted thereon, thus manufacturing an IC/glass connecting structure.

[Manufacturing of Connected Member 3]

The film-like adhesives of Examples 1 to 3 and Comparative Examples 1 to 3 each was transferred in a size of 2×15 mm to a glass board having an ITO membrane on its entire surface (corning #1737 having an outward form of 38 mm×28 mm and a thickness of 0.5 mm) from the PET resin film. An IC chip (outward form 1.0 mm×10 mm, thickness 0.55 mm, size of bump 50 μm×50 μm, pitch of bump 50 μm) was heated and pressed at 150° C. for 5 seconds with applying a load of 80 MPa (converted value for the bump area) to be mounted thereon, thus manufacturing an IC/ITO connecting structure.

[Manufacturing of connected member 4]

The Film-Like Adhesives of Examples 1 to 3 and Comparative Examples 1 to 3 each was transferred in a size of 2×15 mm to a glass board having a SiN membrane on its entire surface (corning #1737 having an outward form of 38 mm×28 mm and a thickness of 0.5 mm) from the PET resin film. An IC chip (outward form 1.0 mm×10 mm, thickness 0.55 mm, size of bump 50 μm×50 μm, pitch of bump 50 μm) was heated and pressed at 150° C. for 5 seconds with applying a load of 80 MPa (converted value for the bump area) to be mounted thereon, thus manufacturing an IC/SiN connecting structure.

[Evaluation of Connection Resistance]

A resistance value between adjacent circuits (the maximum value in 14 terminals measured) in the glass board connected member having IC chip/ITO pattern obtained in the manufacturing of connected member 1 was measured by using a multimeter, and the result is shown in Table 2. It is noted that the resistance value was measured immediately after the connection (in Table 2, represented as “resistance value (before test)” and after conducting a high temperature and high humidity test (85° C., 85% RH) for 100 hours (in Table 2, represented as “resistance value (after test)”). In resistance measurement conducted as described above, a satisfactory value of 10Ω or less was obtained in Examples 1, 2, and 3 both before and after the high temperature and high humidity test. In Comparative Example 3, connection could not be established. In Comparative Examples 1 and 2, connection could not be realized after the high temperature and high humidity test.

TABLE 2

| | Mounting | Resistance value | Resistance value |
|---|---|---|---|
| | condition | (before test) | (after test) |
| Example 1 | 150° C. 10 seconds | 0.8 Ω | 7.6 Ω |
| Example 2 | 150° C. 10 seconds | 1.2 Ω | 8.8 Ω |
| Example 3 | 150° C. 10 seconds | 0.7 Ω | 8.1 Ω |
| Comparative | 150° C. 10 seconds | 2.5 Ω | 100 Ω or more |
| Example 1 | | | |
| Comparative | 150° C. 10 seconds | 22 Ω | 100 Ω or more |
| Example 2 | | | |
| Comparative | 150° C. 10 seconds | 100 Ω or more | 100 Ω or more |
| Example 3 | | | |

[Measurement of Adhesion Strength]

For the IC/glass connecting structural bodies, the IC/ITO connecting structural bodies, and the IC/SiN connecting structural bodies obtained in the manufacturing of connected member 2, 3, and 4, shear adhesion strength immediately after the connection (initial adhesion strength) and shear adhesion strength after conducting a high temperature and high humidity test (85° C., 85% RH) for 100 hours (adhesion strength after the high temperature and high humidity test, represented as “adhesion strength after test” in Table 3) were measured by using a bond tester (manufactured by Dyge company). Measurement was performed twice on each of the connecting structural bodies independently. The averages of the measurement results are shown in Table 3. In the measurement of the adhesion strength conducted as described above, high adhesion strength was obtained for all of the structural bodies before and after the high temperature and high humidity test in Examples 1, 2, and 3. On the other hand, in Comparative Example 1 not containing the organoaluminum complex, or in Comparative Example 2 not containing the silane coupling agent, the adhesion strength was low for the IC/ITO connecting structure or the IC/SiN connecting structure. Also, in Comparative Example 3 containing an organic titanium complex, the adhesion strength was low for all of the connecting structures.

TABLE 3

| | IC/glass connecting | | IC/ITO connecting | | IC/SiN connecting | |
|---|---|---|---|---|---|---|
| | structural body | | structural body | | structural body | |
| | Initial | Adhesion | Initial | Adhesion | Initial | Adhesion |
| | adhesion | strength | adhesion | strength | adhesion | strength |
| | strength | after test | strength | after test | strength | after test |
| | (MPa) | (MPa) | (MPa) | (MPa) | (MPa) | (MPa) |
| Example 1 | 42 | 43 | 25 | 31 | 19 | 34 |
| Example 2 | 40 | 44 | 22 | 34 | 16 | 35 |
| Example 3 | 44 | 38 | 22 | 28 | 18 | 34 |
| Comparative | 13 | 47 | 3.6 | 29 | 1.1 | 29 |
| Example 1 | | | | | | |
| Comparative | 15 | 33 | 2.5 | 1.3 | 4.2 | 2.5 |
| Example 2 | | | | | | |
| Comparative | 3.2 | 2.2 | 4.6 | 2.2 | 2.1 | 2.3 |
| Example 3 | | | | | | |

[External Appearance of Connecting Structural Body]

External appearance of an interfacial surface of the connecting structural body is shown in Table 4. In observation of the external appearance of the connecting structural body conducted as described above, peeling off hardly occurred in any of the connecting structural bodies in Examples 1, 2, and 3; however, relatively large number of peeling off occurred in the IC/ITO connecting structure and the IC/SiN connecting structure in Comparative Examples 1 and 2. Also, in Comparative Example 3, adhesion was not achieved in any of the connecting structural bodies.

TABLE 4

| | IC/glass | IC/ITO | IC/SiN |
|---|---|---|---|
| | connecting | connecting | connecting |
| | structural body | structural body | structural body |
| Example 1 | No peeling off | Slight peeling | Slight peeling |
| | | off at ITO | off at SiN |
| | | interface | interface |
| Example 2 | No peeling off | Slight peeling | Slight peeling |
| | | off at ITO | off at SiN |
| | | interface | interface |
| Example 3 | No peeling off | Slight peeling | Slight peeling |
| | | off at ITO | off at SiN |
| | | interface | interface |
| Comparative | No peeling off | Partial peeling | Partial peeling |
| Example 1 | | off at ITO | off at SiN |
| | | interface | interface |
| Comparative | No peeling off | Partial peeling | Partial peeling |
| Example 2 | | off at ITO | off at SiN |
| | | interface | interface |
| Comparative | Peeling off at | Peeling off at | Peeling off at |
| Example 3 | entire surface of | entire surface of | entire surface of |
| | glass interface | ITO interface | SiN interface |

As is apparent from the results shown in Tables 2 to 4, it was confirmed that, according to the adhesive films and the circuit member connecting structures using them of Examples 1 to 3, the connection resistance was sufficiently reduced and sufficient adhesion strength was obtained in comparison with the adhesive films and the circuit member connecting structures using them of Comparative Examples 1 to 3. Moreover, it was confirmed that the connection resistance and the adhesion strength were maintained sufficiently after the high temperature and high humidity test for long period of time and the external appearance of the connection surface was satisfactory.

### REFERENCE SIGNS LIST

1 film-like adhesive, 2 semiconductor device, 5 adhesive component, 7 conductive particles, 10 circuit connecting member, 11 insulating material, 20 first circuit member, 21 circuit board (first circuit board), 21a main surface, 22 circuit electrode (first circuit electrode), 30 second circuit member, 31 circuit board (second circuit board), 31a main surface, 32 circuit electrode (second circuit electrode), 40 film-like circuit connecting material, 92 board, 94 wiring member, 95 connecting member, 96 electrode, 97 back surface electrode, 98 light receiving surface, 99 back surface, 100A, 100B solar cell, 200 solar cell module.

1. An adhesive composition comprising an organoaluminum complex (A), a silane coupling agent (B), and a curable component (C).

2. The adhesive composition according to claim 1, wherein the organoaluminum complex (A) is represented by formula (1): 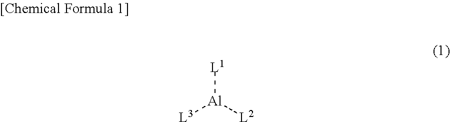
wherein, L¹, L², and L³ each independently represent an alkoxy anion, a conjugated anion of β-diketone, or a conjugated anion of β-ketoester; and L¹, L², and L³ may be the same or different from each other.

3. The adhesive composition according to claim 1, wherein the silane coupling agent (B) is a methacryl group-containing silane coupling agent or an acryl group-containing silane coupling agent.

4. The adhesive composition according to claim 1, wherein the curable component (C) comprises a radical polymerizable compound and a radical polymerization initiator.

5. The adhesive composition according to claim 1, further comprising a film forming material.

6. A film-like adhesive prepared by forming the adhesive composition according to claim 1 into a film shape.

7. A circuit connecting material comprising the adhesive composition according to claim 1.

8. The circuit connecting material according to claim 7, further comprising conductive particles.

9. A circuit member connecting structure comprising:
a first circuit member having a first circuit electrode formed on a main surface of a first circuit board;
a second circuit member having a second circuit electrode formed on a main surface of a second circuit board; and
a circuit connecting member which is formed between the main surface of the first circuit board and the main surface of the second circuit board and connects the first circuit member and the second circuit member in the condition in which the first circuit electrode and the second circuit electrode are arranged facing each other,
wherein the circuit connecting member is composed of a cured material of the circuit connecting material according to claim 7, and the first circuit electrode and the second circuit electrode are electrically connected to each other.

10. The circuit member connecting structure according to claim 9, wherein at least a part of an adherend surface of the first circuit member or the second circuit member is composed of an inorganic material.

11. A method for manufacturing the circuit member connecting structure according to claim 9, wherein the circuit connecting material according to claim 7 is placed between the main surface of the first circuit board and the main surface of the second circuit board, the circuit connecting material is heated and pressed to be cured via the first circuit member and the second circuit member, thereby connecting the first circuit member and the second circuit member, and electrically connecting the first circuit electrode and the second circuit electrode.

12. The method according to claim 11, wherein at least a part of an adherend surface of the first circuit member or the second circuit member is composed of an inorganic material.

13. Use of the circuit connecting material according to claim 7 for connecting a first circuit member having a first circuit electrode formed on a main surface of a first circuit board and a second circuit member having a second circuit electrode formed on a main surface of a second circuit board in the condition in which the first circuit electrode and the second circuit electrode are arranged facing each other.

14. The use according to claim 13, wherein at least a part of an adherend surface of the first circuit member or the second circuit member is composed of an inorganic material.

15. A solar cell module comprising a solar cell having an electrode; a wiring member; and a connecting member connecting the solar cell and the wiring member so that the electrode and the wiring member are electrically connected to each other,
wherein the connecting member contains a cured material of the circuit connecting material according to claim 7.

16. Use of the circuit connecting material according to claim 7 for connecting a solar cell having an electrode and a wiring member so that the electrode and the wiring member are electrically connected to each other.

17. A cured material of the adhesive composition according to claim 1.
